(19) United States
(12) Patent Application Publication
(10) Pub. No.: US 2009/0001589 A1
(43) Pub. Date: Jan. 1, 2009

(54) NOR FLASH DEVICE AND METHOD FOR FABRICATING THE DEVICE

(76) Inventor: Sung-Joong Joo, Gangnam-gu (KR)

Correspondence Address: SHERR & VAUGHN, PLLC, 620 HERNDON PARKWAY, SUITE 200, HERNDON, VA, 20170, US

(21) Appl. No.: 12/146,108

(22) Filed: Jun. 25, 2008

(30) Foreign Application Priority Data
Jun. 26, 2007 (KR) 102007-0062806

(51) Int. Cl. H01L 21/768; H01L 23/522

(52) U.S. Cl. 257/758; 438/637; 257/E23.145; 257/E21.585

(57) ABSTRACT

An NOR flash memory device having a back end of line (BEOL) structure, the BEOL structure including a substrate having a conductive region, a first intermetal dielectric layer formed on the substrate, a first metal line formed on the conductive region, a second intermetal dielectric layer formed on the first metal line and the first inter metal dielectric, a first contact extending through the second intermetal dielectric layer, and a second metal line connected to the first metal line through the first contact. At least one of the first contact and the first and second metal lines is composed of copper and at least one of the first and second intermetal dielectric layers is composed of a low diectrice material. The use of copper metal lines and intermetal dielectric layers composed of a low-k (k=3.0) material makes it possible to improve 40% or more in the time constant delay.

The present application claims priority under 35 U.S.C. §119 to Korean Patent Application No. 10-2007-0062806 (filed on Jun. 26, 2007), which is hereby incorporated by reference in its entirety.

### BACKGROUND

In order to meet a demand for thin, highly integrated, and high speed, ultra large scale integrated (ULSI) circuit, a new technology even in a flash device is needed. A material of an intermetal dielectric (IMD) and a technology for forming the same even in a NOR flash device are important factors to enhance the characteristics of the device. First, delay time according to kinds of materials will be described below.

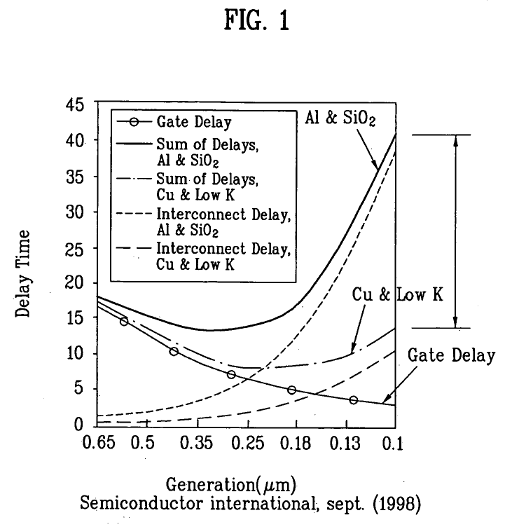

Example FIG. 1 is a graph showing a relation of delay time according to kinds of materials, wherein a horizontal axis indicates a line width and a vertical axis indicates delay time. As illustrated in example FIG. 1, when a low dielectric thin film is applied to a line having a line width of 0.13 μm or less, the delay time may be suddenly increased in the case of Al/SiO₂. However, when Cu/Low-k is applied thereto, the delay time can be reduced by about 50% as compared to Al/SiO₂. Furthermore, the number of layers of a metal line can be reduced from 12 to 6. Therefore, since a complicated metal line process can be simplified, power consumption of the device can be reduced by about 30%, and the manufacturing cost of the device can be reduced by about 30%. An intermetal dielectric material is on the rise as a core technology in a development of a next generation semiconductor device.

Even in the case of a NOR flash device, its size may be reduced so that time constant RC, delay, cross talk, noise, and power dissipation occur. As a result, in a BEOL, a high conductive material and a low-k dielectric material may be used as an intermetal dielectric material. However, in a structure of a BEOL of a NOR flash device, an SiO₂ thin film which serves as the intermetal dielectric (IMD) material of the currently used metal line, has a dielectric constant of between 3.9 to 4.2, which is too high. This may cause a severe problem in consideration of the high integration and the high speed of the semiconductor device of 0.18 μm grade or more, etc. Also, for achieving such high integration and high speed, a critical dimension (CD) of 0.13 μm and a driving speed of about 2000 MHz may be needed. However, since a line material of a conventional NOR flash device is composed of aluminum, there is a problem in that electric resistance is too high.

### SUMMARY

Embodiments relate to a NOR flash device, such as 90 nm grade, etc., and in particular, to a back-end-of-line (BEOL) structure in a NOR flash device and a method for fabricating the device.

Embodiments relate to a NOR flash device and a method for fabricating the device using copper and a low-k dielectric material in a BEOL structure.

Embodiments relate to a NOR flash device and a method for fabricating the device that can prevent diffusion of copper which may be induced by an application of copper and low-k dielectric material in a BEOL structure.

Embodiments relate to a NOR flash memory having a BEOL structure that can include at least one of the following: a substrate having a conductive region; a first inter metal dielectric formed on and/or over the substrate; a first metal line formed in the conductive region; a second inter metal dielectric covering the first metal line and the first inter metal dielectric; a first contact penetrating through the second inter metal dielectric; and a second metal line connected to the first metal line through the first contact. In accordance with embodiments, at least one of the first contact and the first and second metal lines are composed of copper and at least one of the first and second inter metal dielectrics is composed of a low diectrice material.

Embodiments relate to a method for fabricating a NOR flash memory having a BEOL structure and may include at least one of the following steps: forming a conductive region in a substrate; and then forming on and/or over the substrate a first inter metal dielectric having a trench exposing the conductive region; and then forming a first metal line in the trench; and then forming on the uppers of the first metal line and the first inter metal dielectric a second inter metal dielectric having a hole exposing the first metal line; and then forming a first contact and a second metal line in the hole. In accordance with embodiments, at least one of the first contact and the first and second metal lines is composed of copper and at least one of the first and second inter metal dielectrics is composed of a low-k dielectric material.

Embodiments relate to an apparatus that may include at least one of the following: a substrate having a conductive region; a first intermetal dielectric layer formed on the substrate; a first metal line formed on the conductive region; a second intermetal dielectric layer formed on the first metal line and the first inter metal dielectric; a first contact extending through the second intermetal dielectric layer; and a second metal line connected to the first metal line through the first contact. In accordance with embodiments, at least one of the first contact and the first and second metal lines is composed of copper and at least one of the first and second inter metal dielectrics is composed of a low-k dielectric material.

Embodiments relate to a method that may include at least one of the following steps: forming a conductive region in a substrate; and then forming a first intermetal dielectric layer on the substrate, the first intermetal dielectric layer having a trench exposing the conductive region; and then forming a first metal line in the trench; and then forming a second intermetal dielectric layer on the first metal line and the first intermetal dielectric, the second intermetal dielectric layer having a hole exposing the first metal line; and then forming a first contact and a second metal line in the hole. In accordance with embodiments, at least one of the first contact and the first and second metal lines is composed of copper and at least one of the first and second intermetal dielectric layers is composed of a low-k dielectric material.

### DRAWINGS

Example FIG. 1 illustrates a graph showing a relation of delay time according to various material compositions.

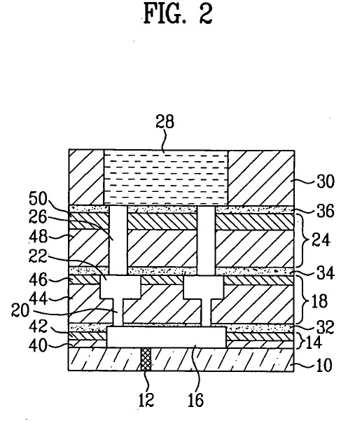

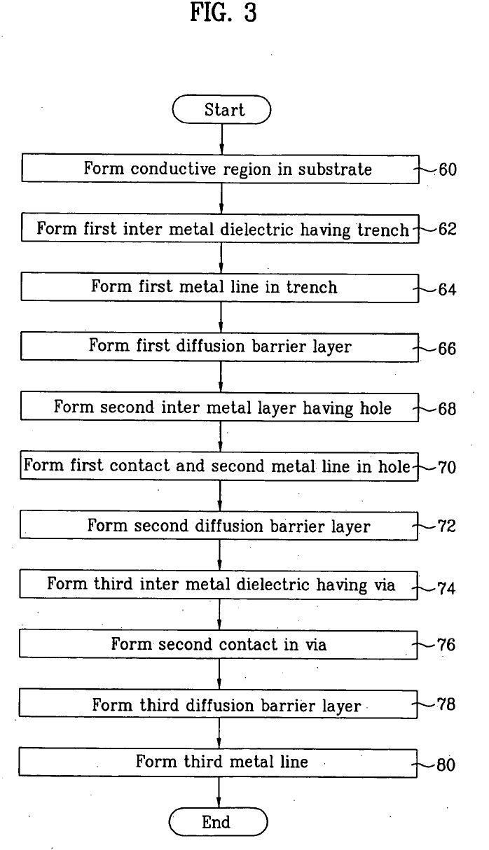

Example FIGS. 2 and 3 illustrates a BEOL structure of a NOR flash device and a method for fabricating a NOR flash device in accordance to embodiments.

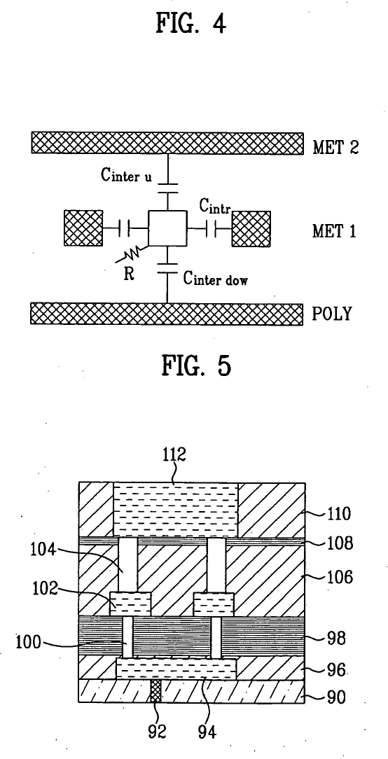

Example FIG. 4 illustrates a simulation of the flash memory device in accordance with embodiments.

Example FIG. 5 illustrates a BEOL structure of a NOR flash device.

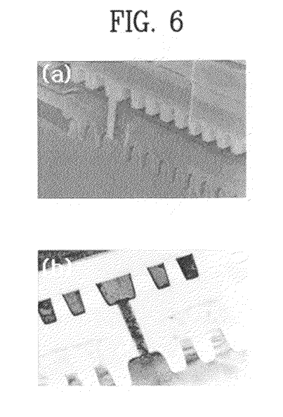

Example FIGS. 6(a) and 6(b) illustrate cross-sectional images of a first metal line and a conductive region obtained by SEM and TEM, respectively, in accordance with embodiments.

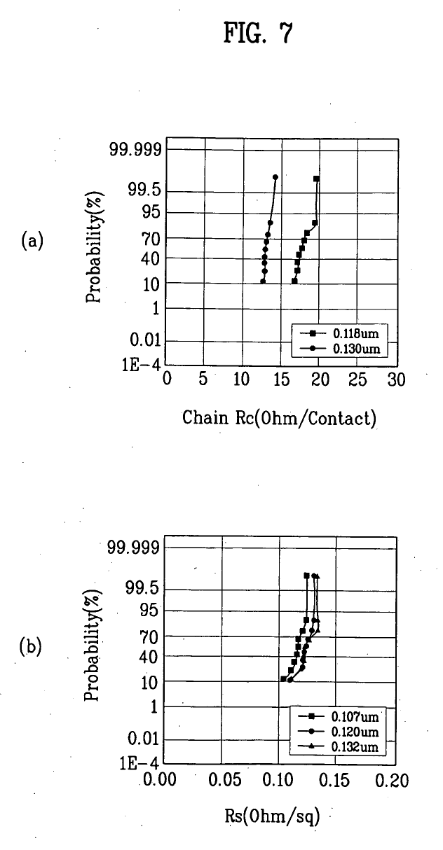

Example FIGS. 7(a) and 7(b) illustrate a relation between resistance and probability of a conductive region and a first metal line, in accordance with embodiments.

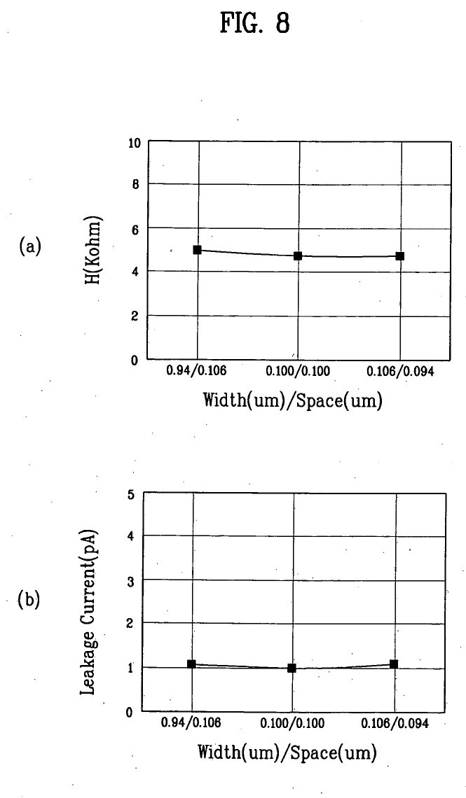

Example FIGS. 8(a) and 8(b) illustrate an open characteristic and a short characteristic of a first metal line in accordance with embodiments.

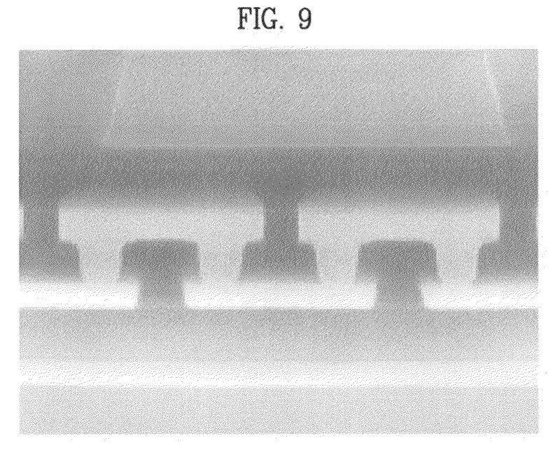

Example FIG. 9 illustrate cross-sectional images of a first contact and a second metal line obtained by SEM, in accordance with embodiments.

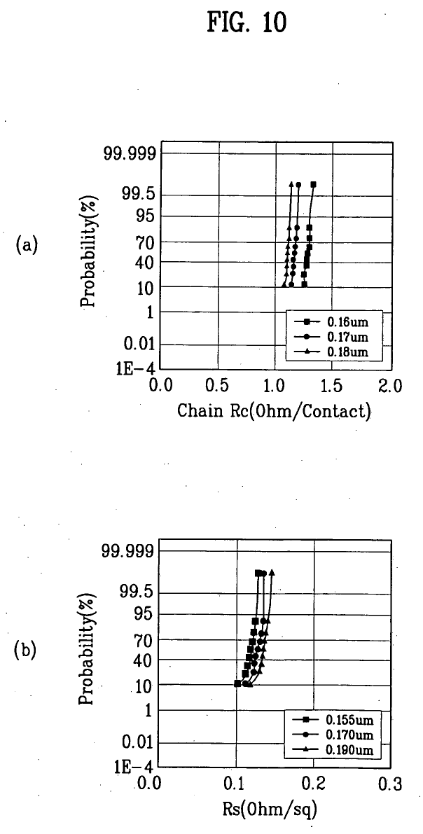

Example FIGS. 10(a) and 10(b) illustrate a relation between resistance and probability of a first contact and a second metal line, in accordance with embodiments.

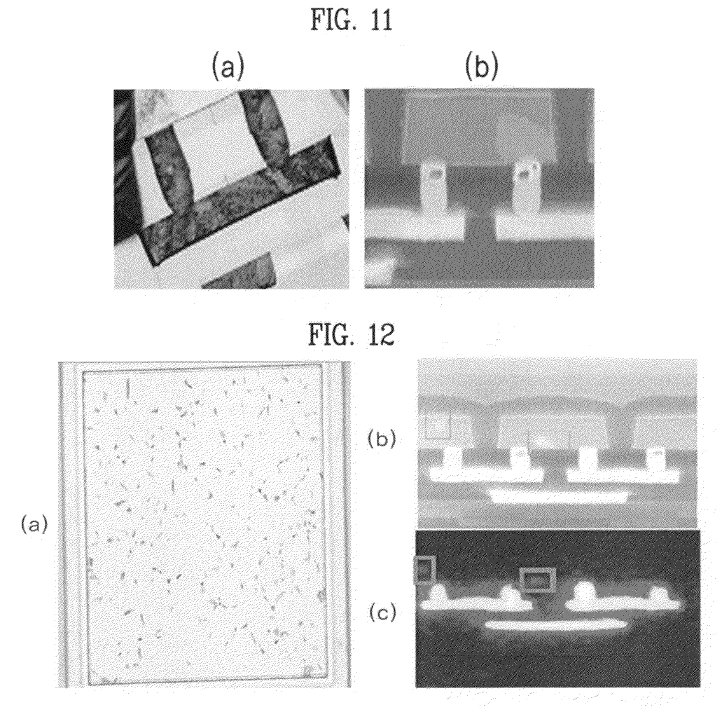

Example FIGS. 11(a) and 11(b) illustrate cross-sectional images of a second contact and a third metal line obtained by TEM and SEM, respectively, in accordance with embodiments.

Example FIGS. 12(a) to 12(c) illustrate an aluminum pad, an SEM image for a third metal line and an AES image for a third metal line, respectively, in accordance with embodiments.

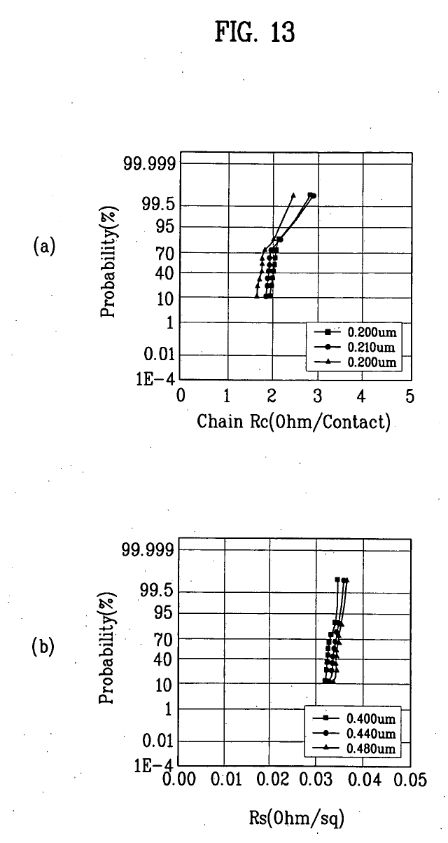

Example FIGS. 13(a) and 13(b) illustrate a resistance characteristic of a second contact and a third metal line, in accordance with embodiments.

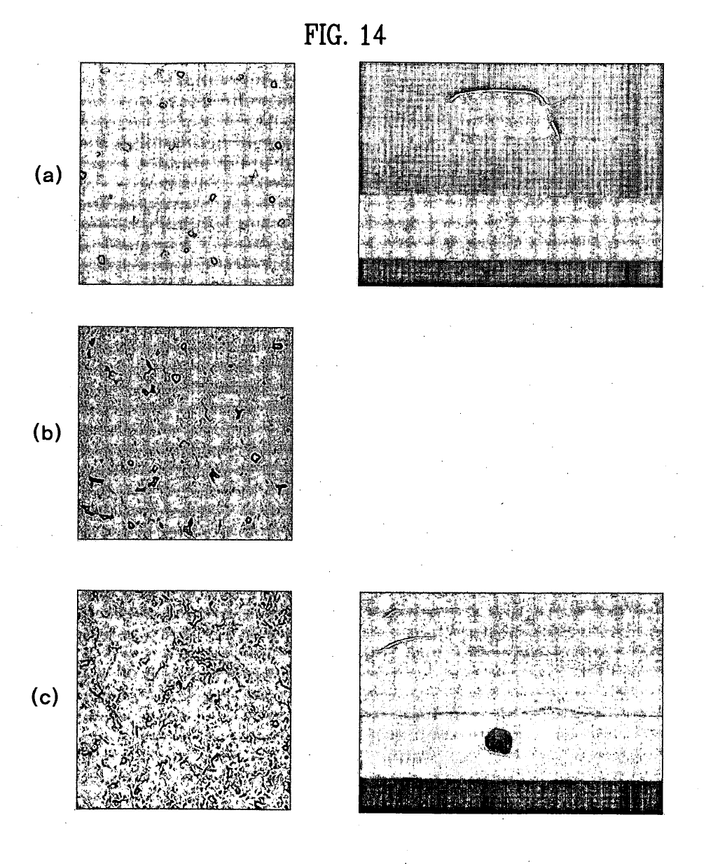

Example FIGS. 14(a) to 14(c) illustrate a copper diffusion shape according to an annealing condition through an optical device and an SEM, in accordance with embodiments.

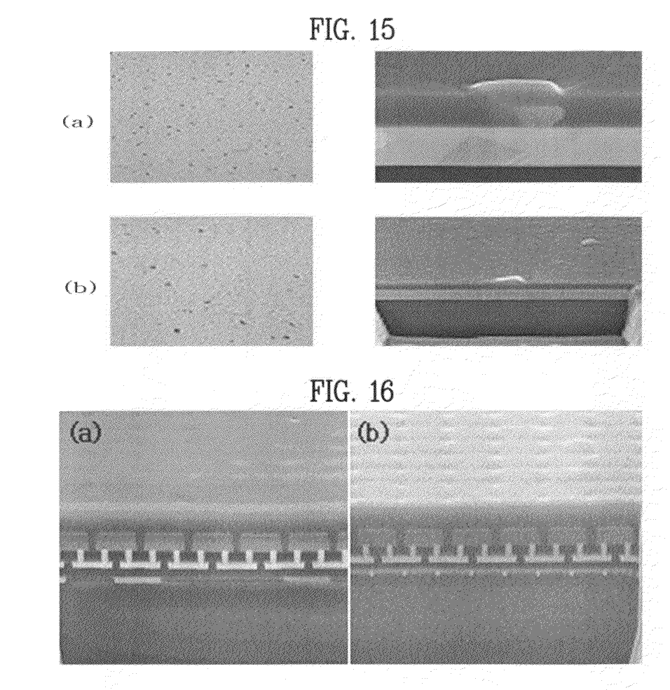

Example FIGS. 15(a) and 15(b) illustrate cross-sectional images of a pad and a third metal line when TiSiN (2×100) and TiSiN (4×50) each is used as a third diffusion barrier layer, in accordance with embodiments.

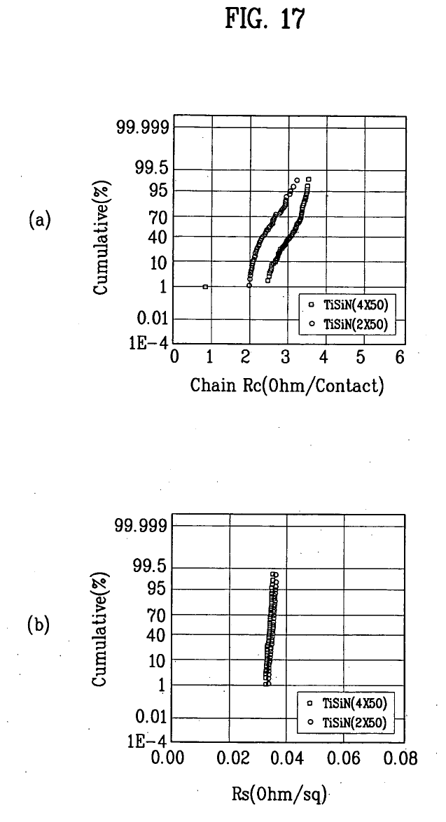

Example FIGS. 16(a) and 16(b) illustrate FIB images of a center and an edge when TiSiN (4×50) as a third barrier layer is actually applied to a 90 nm NOR flash device, in accordance with embodiments.

Example FIGS. 17(a) and 17(b) illustrate electrically measured data in a target size of sheet resistance and contact resistance of a full point when TiSiN (2×50) and TiSiN (4×50) as the third barrier layer are applied, in accordance with embodiments.

### DESCRIPTION

Hereinafter, a structure of a NOR flash device and a method for fabrication the device in accordance with embodiments will be described below with reference to the accompanying drawings.

As illustrated in example FIG. 2, in a NOR flash device having a back end of line (BEOL) structure in accordance with embodiments, the BEOL structure may includes substrate 10, first intermetal dielectric 14, first metal line 16, second inter metal dielectric 18, first contact 20 and second metal line 22. More specifically, substrate 10 may have conductive region 12. First intermetal dielectric 14 may be formed on and/or over substrate 10 and first metal line 16 may be formed extending through first intermetal dielectric 14 and on and/or over substrate 10 including conductive region 12. Second intermetal dielectric 18 may be formed on and/or over first metal line 16 and first intermetal dielectric 14. First contact 20 may be formed extending through second intermetal dielectric 18 and second metal line 22 may be connected to first metal line 16 through first contact 20. At least one of first contact 20 and first and second metal lines 16 and 22 may be composed of copper. At least one of first and second inter metal dielectrics 14 and 18 may be composed of a low-k dielectric material.

In accordance with embodiments, the BEOL structure may further include third intermetal dielectric 24, second contact 26 and third metal line 28. Third intermetal dielectric 24 may be formed on and/or over second metal line 22 and second intermetal dielectric 18. Second contact 26 may be formed extending through third intermetal dielectric 24. Third metal line 28 may be connected to second metal line 22 through second contact 26. Second contact 26 may be composed of copper and third intermetal dielectric 24 may be composed of a low-k dielectric material. The BEOL structure may further include the first, second, and third diffusion barrier layers 32, 34, and 36. First diffusion barrier layer 32 may be formed interposed between first metal line 16 and second inter metal dielectric 18. Second diffusion barrier layer 34 may be formed interposed between second metal line 22 and third intermetal dielectric 24. Third diffusion barrier layer 36 may be formed interposed between second contact 26 and fourth inter metal dielectric 30. Any one of first, second and third intermetal dielectrics 14, 18, and 24 may have a multi-layer structure including low-k dielectric material layers 40, 44, and 48 and tetraethylortho silicate glass TEOS oxide films 42, 46, and 50 formed on and/or over low-k dielectric material layers 40, 44, and 48. Fourth intermetal dielectric 30 may be formed on and/or over third diffusion barrier layer 36.

As illustrated in example FIGS. 2 and 3, in step 60, conductive region 12 may be formed in semiconductor substrate 10. A predetermined semiconductor structure may be formed on and/or over semiconductor substrate 10 including conductive region 12. After performing step 60, step 62 may include forming first intermetal dielectric 14 having a trench therein exposing conductive region 12 on and/or over substrate 10. After performing step 62, first metal line 16 may then be formed in the trench of first inter metal dielectric 14 in step 64. After performing step 64, first diffusion barrier layer 32 may then be formed on and/or over first intermetal dielectric 14 in step 66. After performing step 66, second intermetal dielectric 18 having a damascene hole exposing first metal line 16 may be formed on and/or over first diffusion barrier layer 32 in step 68. After performing step 68, first contact 20 and second metal line 22 may be formed in the damascene hole of second intermetal dielectric 18 in step 70. First contact 20 may be formed extending through second intermetal dielectric 18 to connect first metal line 16 and second metal line 22. After performing step 70, second diffusion barrier layer 34 may then be formed on and/or over second metal line 22 and second intermetal dielectric 18 in step 72. After performing step 72, third intermetal dielectric 24 having a via exposing second metal line 22 may then be formed on and/or over second diffusion barrier layer 34 in step 74. After performing step 74, second contact 26 may then be formed in the via of third intermetal dielectric 24 in step 76. After performing step 76, third diffusion barrier layer 36 may then be formed on and/or over second contact 26 in step 78. After performing step 78, third metal line 28 and fourth intermetal dielectric 30 may then be formed on and/or over third diffusion barrier layer 36 in step 80. Third metal line 28 may be connected to second metal line 22 through second contact 26 extending through third intermetal dielectric 24.

As illustrated in example FIG. 2, in accordance with embodiments, at least one of first metal line 16, first contact 20, second metal line 22 and second contact 26 may be composed of a metal such as copper. For example, such a copper layer may be formed by a metal deposition method, such as an electro plating method, a chemical vapor deposition (CVD) method or a physical vapor deposition (PVD) method, etc. The formed copper layer may then be polished by a chemical mechanical polishing process, etc., thereby making it possible to obtain metal lines 16 and 22 and metal contacts 20 and 26. As described above, when metal lines 16 and 22 and metal contacts 20 and 26 are composed of copper, they may be formed through a single damascene process or a dual damascene process. In this case, the hole of second intermetal dielectric 18 formed in step 68 may be a damascene hole. For example, first contact 20 and second metal line 22 may be formed by a damascene process, in particular, a dual damascene process. A material layer for second intermetal dielectric 18 may be disposed on and/or over first diffusion barrier layer 32 and may then be then etched by a patterning using a photosensitive film pattern to generate a damascene hole. A diffusion barrier layer may then be formed on and/or over inner walls of the generated damascene hole. Copper material may then be deposited on and/or over the diffusion barrier layer, making it possible to form second contact 20 and second metal line 22 by the CMP process. Example FIG. 2 illustrates a BEOL structure in which three layers of a metal line are manufactured using a low-k dielectric material and copper by a damascene process.

When respective metal contacts 20 and 26 and metal lines 16 and 22 are composed of copper, a diffusion barrier layer for preventing diffusion of copper to a neighboring intermetal dielectric layer may be formed. For instance, in addition to first, second, and third diffusion barrier layers 32, 34, and 36, a plurality of diffusion barrier layers for preventing the diffusion of copper may be prepared between the copper layer and the intermetal dielectric. The diffusion barrier layer may be formed by a PVD method, a CVD method, or an atomic layer deposition (ALD) method and be composed of at least one of TaN, Ta, TaN/Ta, TiSiN, WN, TiZrN, TiN and Ti/TiN, etc. When first metal line 16 is composed of copper, first diffusion barrier layer 32 may perform a role of preventing the diffusion of copper of first metal line 16 to second intermetal dielectric 18. Also, when second metal line 22 is composed of copper, second diffusion barrier layer 34 may perform a role of preventing the diffusion of copper of second metal line 22 to third intermetal dielectric 24. Third metal line 28 may be composed of metals such as copper or aluminum. However, since second contact 26 is composed of copper, third diffusion barrier layer 36 may perform a role of preventing the diffusion of copper to third metal line 28 composed of aluminum.

In the NOR flash device, since a subsequent annealing time may be long, when the subsequent annealing process is progressed, copper may be diffused to third metal line 28 of aluminum in the case where the thickness of third diffusion barrier layer 36 is thin. When copper is diffused, a problem in a subsequent bonding or package may occur. To prevent this, the thickness of third diffusion barrier layer 36 composed of TiSiN may be formed thicker. The thickness of third diffusion barrier layer 36 may be formed in a range between 2×15 Å to 4×100 Å, and preferably, may be formed at 4×50 Å. In the expression of the thickness, a front portion of “x” indicates the number of layers and a rear portion of X indicates the thickness of each layer. For example, 4×50 Å has a four-layer structure such that the thickness of each layer is 50 Å.

Meanwhile, first to fourth intermetal dielectrics 14, 18, 24, and 30 may be composed of a low-k dielectric material. For example, at least one of first, second and third intermetal dielectric 14, 18, or 24 may have a multi-layer stacked structure that includes low-k dielectric material layers 40, 44 or 48 and TEOS oxide layer 42, 46, or 50 formed on and/or over low-k dielectric material layers 40, 44, or 48. In other words, to form first intermetal dielectric 14, low-k dielectric material layer 40 may be formed on and/or over substrate 10. After forming low-k dielectric material layer 40, TEOS oxide film 42 may then be formed on and/or over low-k dielectric material layer 40. In a silmary way thereto, to form second intermetal dielectric 18, low-k dielectric material layer 44 may be formed on and/or over first diffusion barrir layer 32. TEOS oxide layer 46 may then be formed on and/or over low-k dielectric material layer 44. Also, to form third intermetal dielectric 24, low-k dielectric material layer 48 may be formed on and/or over second diffusion barrier layer 34. TEOS oxide layer 50 may then be formed on and/or over low-k dielectric material layer 48. To form fourth intermetal dielectric 30, a low-k dielectric material layer 30 may be formed on and/or over third diffusion barrier layer 36. Low-k dielectric material layers 40, 44, 48 and 30 may be composed of a black diamond (BD) film having a low-k (k=3.0) may be used and a block film may be used as diffusion barrier layers 32, 34, and 36. In the BEOL illustrated in example FIG. 2, aluminum may be used in a pad portion. Each intermetal dielectric 14, 18, and 24 is illustrated in example FIG. 2 as having a multi-layered structure including low-k dielectric material layers 40, 44, and 48 and TEOS oxide layers 42, 46, and 50 are stacked in a double layer. However, embodiments are not limited thereto and each intermetal dielectric 14, 18, and 24 may have a single layer structure or a structure having at least three stacked layers.

Hereinafter, in the NOR flash device, effects of the BEOL structure in accordance with embodiments and characteristics of each region in the BEOL structure in accordance with embodiments will be described with reference to the accompanying drawings, as compared to another BEOL structure.

Example FIG. 4 illustrates a view schematically showing a simulation. First, time constant delay of a stack using aluminum and fluorinated silicate glass (FSG) and a stack using copper and a low-k dielectric material (hereinafter, referred to as “low-k”) is schematically simulated using a HSPICE (Y-2006.09) and a Rphael (Z-2006. 12-SPI) device. Also, a patterning process for first metal line 16 and conductive region 12 of substrate 10 among patterning processes in a BEOL process of 90 nm is setup using a 306C ArF photolithography device available from Nicon Co. using argon fluoride (Arf) having a wavelength of 193 nm, which is shorter than a wavelength 248 nm of Krypton Fluoride (KrF), as a light source.

In the BEOL structure in accordance with embodiments, a producer device available from AMAT Co. may be used to deposit the low-k for the intermetal dielectric, with a BD film being used as a low-k IMD, and a block film being used as the diffusion barrier layer. In addition, the intermetal dielectric in accordance with embodiments may be deposited by the porous low-k, polished by the CMP process, and ashed. Also, electrical features, such as metal resistance, contact resistance, open and short, etc., are measured by an auto electrical data measuring device. Also, integrated profiles of copper and low-k are analyzed by a transmission electro microscope (TEM) and a scanning electro microscope (SEM).

In addition, the following conditions may be applied to show the above-mentioned copper diffusion and shapes for solving the same. The TiSiN layer performing a role of the diffusion barrier layer may be deposited by a thermal decomposition of a precursor referred to as Tetrakis-dimethyl-amino-titaniume (TDMAT) at a state where substrate temperature is about 350° C. First, to test a blank wafer, oxide (ox) may be thermally formed to be stacked to a thickness of 1000 Å on and/or over a p-type wafer and to compare and judge the characteristics of the diffusion barrier layer composed of TiSiN, TaN(150 Å)/Ta(150 Å)/Seed Cu(3000 Å)/TiSiN(2×50)/Al(7000 Å) may then be sequentially formed in a multi-layered stacked structure. Thereafter, the copper diffusion according to temperature using an annealing system of the producer device available form AMAT Co. is measured using an auge electro microsope (AES) and an optical image device. Next, to test the wafer having the pattern, patterns are generated to last UV erase from second contact 26 of the actual 90 nm NOR flash device. For the optimal third metal line 28, TiSiN(2×50×2)/Ti(40 Å)/Al(7000 Å)/In-situ Ti/TiN (460 Å) may be deposited. To review the copper diffusion shape, the pad is confirmed by the optical image device and to confirm the cross section image, the via void of second contact 26 is confirmed by the SEM. The contact resistance of second contact 26 is measured through the subsequent auto electrical data measuring device.

Embodiments are compared to other devices and the respective characteristics of such embodiments will be reviewed in detail under the above-mentioned conditions. Example FIG. 5 illustrates a BEOL structure of a NOR flash device including first metal line 94 connected to contact 92 of substrate 90. First metal line 94 is connected to second metal line 102 through contact 100 and second metal line 102 is connected to third metal line 112 through contact 104. Intermetal dielectrics 96, 98, 106, 108, and 110 are prepared between the respective metal lines. Each wiring 94, 102, and 112 may be composed of aluminum, intermetal dielectrics 96 and 106 may be composed of un-doped silicate glass (USG), intermetal dielectrics 98 and 108 may be composed of oxide-TEOS, and aluminum is used in the pad portion. In the 90 nm NOR flash device, the simulation results of RC delay values in the case of using Al and USG as illustrated in example FIG. 5 and the simulation results of RC delay values in the case of using copper and low-k as illustrated in example FIG. 2 are indicated in Table 1.

TABLE 1

| | | IC delay |
|---|---|---|
| Division | Material | [ps/stg] |
| METAL 1 | Al/USG | 1099 |
| | Cu/Low-k | 922 |
| METAL 2 | Al/USG | 1092 |
| | Cu/Low-k | 742 |

Herein, METAL 1 is first metal lines 16 and 94 and METAL 2 is second metal lines 22 and 102. As can be appreciated from Table 1, METAL 1 can obtain a gain of RC delay of about 10% using low-k and Cu, and METAL 2 can obtain a gain of about 40%.

Example FIGS. 6(a) and 6(b) each illustrate cross-sectional images of first metal line 16 and conductive region 12 obtained by SEM and TEM, respectively. As illustrated in example FIGS. 6(a) and 6(b), where the etched, ashed, and cleaned trench is defined and a transverse section of a profile of first metal line 16 subjected to the CMP is photographed by the SEM and the TEM, respectively, it can be appreciated that the phenomenons of oxygen plasma damage of the trench due to use of low-k or shrinkage or bowing of low-k due to a wet strip do not occur. Also, the depth of the actual first metal line 16 may be 220 nm.

Example FIGS. 7(a) and 7(b) are graphs illustrating a relationship between resistance and probability of conductive region 12 and first metal line 16. More specifically, as illustrated in example FIG. 7(a), a graph showing chain contact resistance (R_{C}) when the line width of conductive region 12 on and/or over an active area (AA) is 0.118 μm and 0.130 μm. The horizontal axis indicates the chain contact resistance (chain R_{C}) and the vertical axis means the probability. As illustrated in example FIG. 7(b), a graph showing the sheet resistance (R_{S}) of first metal line 16 as cumulative probability when the line width of first metal line 16 is 0.107 μm, 0.120 μm, and 0.132 μm. The horizontal axis indicates sheet resistance R_{S} and the vertical axis indicates the probability. As illustrated in example FIG. 7(a), when the line width of conductive region 12 is 0.130 μm, the contact resistance of conductive region 12 is slightly lower than 20 ohm/CC, but experiences few problems. As illustrated in example FIG. 7(b), when the line width of first metal line 16 is 0.120 μm, but has few problems.

Example FIGS. 8(a) and 8(b) are graphs illustrating an open characteristic and a short characteristic of first metal line 16. The horizontal axis indicates a ratio of width/space of first metal line 16. As illustrated in example FIGS. 8(a) and 8(b), the open characteristic and the short characteristic of first metal line 16 for a pitch of 0.200 μm most vulnerable at 90 nm can be appreciated. As illustrated in example FIG. 8(a), although the line width of first metal line 16 is reduced to 0.094 μm, there are few problems of the open characteristic. Herein, the result of few problems of the open characteristic means that due to a small line width the line width is not defined or a breaking phenomenon does not occur. In a viewpoint of the short characteristic, although the line width of first metal line 16 is increased to 0.106 μm, since leakage current is 2 pA or less, it can be appreciated that the short characteristic does not occur.

Example FIG. 9 is images illustrating cross-sections of first contact 20 and second metal line 22 obtained by SEM. The shapes of first contact 20 and second metal wiring 22 obtainable by depositing low-k (k=3) material layer 40 and capping TEOS 42 as first inter metal dielectric 14, making a damascene pattern, depositing first diffusion barrier layer 32 and copper, performing a gap fill with an electro chemical plating (ECP), and then performing a CMP. As illustrated in example FIG. 9, the shrinkage and bowing phenomenons due to a use of low-k does not occur. The actual depth of second metal line 22 is 254 nm and the depth of first contact 20 is about 309 nm.

Example FIGS. 10(a) and 10(b) are graphs illustrating a relationship between the resistance and the probability of first contact 20 and second metal line 22. As illustrated in example FIG. 10(a), the relationship between the contact resistance and the probability when the line width of second metal line 22 is 0.16 μm, 0.170 μm and 0.180 μm. The horizontal axis indicates chain R_{C} and a vertical axis indicates probability. As illustrated in example FIG. 10(b), sheet resistance R_{S} and the cumulative probability of second metal line 22 when the line width of second metal line 22 is 0.155 μm, 0.170 μm, and 0.190 μm. The horizontal axis indicates sheet resistance and a vertical axis indicates probability. It can be appreciated from example FIG. 10(a) that the contact resistance distribution of first contact 20 is good and it can be appreciated from example FIG. 10(b) that the resistance characteristic of second metal line 22 is good.

Example FIGS. 11(a) and 11(b) illustrate cross-sectional images of second contact 26 and third metal line 28 obtained by TEM and SEM, respectively. As illustrated in example FIG. 11(a), the shrinkage and bowing phenomenons due to low-k does not occur. As illustrated in example FIG. 11(b), however, voids are observed at a portion of the uppermost surface of second contact 26.

Example FIG. 12(a) illustrates images of the aluminum pad, example FIG. 12(b) illustrated SEM images for third metal line 28 and example FIG. 12(c) illustrates AES images for third metal line 28. As illustrated in example FIG. 12(a), when via voids occur in second contact 26, it can be appreciated that copper is diffused to the uppermost surface of the pad so that the upper thereof is contaminated. As illustrated in example FIGS. 12(b) and 12(c), analyzing the portion of copper diffusion with SEM and AEC, it can be appreciated that the copper component is actually detected in third metal line 28. The copper diffusion to the pad causes problems in the subsequent bonding and packaging.

Example FIGS. 13(a) and 13(b) are graphs explaining the resistance characteristic of second contact 26 and third metal line 28. As illustrated in example FIG. 13(a), when the line width of second contact 26 is 0.200 μm, 0.210 μm, and 0.220 μm, the relation between the contact resistance and the probability of second contact 26 can be appreciated. As illustrated in example FIG. 13(b), when the line width of third metal line 28 is 0.400 μm, 0.440 μm, and 0.480 μm, the relation between the sheet resistance and the cumulative probability of third metal line 28 can be appreciated. In the stacked structure of Ti(110 Å)/Al(7000 Å)/in-situ Ti/TiN (50 Å/360 Å) on and/or over the lowermost surface of third metal line 28, when the thickness of TiSiN used as the diffusion barrier layer is thin at about 2×50 Å, the role of preventing the copper diffusion is not fully performed. Thereby, copper may be diffused to third metal line 28 as illustrated in example FIGS. 11 and 12.

Example FIGS. 14(a) to 14(c) illustrate images for the copper diffusion shape according to an annealing condition, obtained through the optical device and the SEM. When the annealing is performed for 30 minutes at an N₂ atmosphere of 350° C., 400° C., 450° C., the images shown in example FIGS. 14(a) to 14(c) can be obtained. As illustrated in example FIG. 14(a), when performing the annealing process is performed at 350° C., it can be appreciated that the pad portion (left image) is clear and as a confirmation result of the cross section (right image) of the pad with a focus ion beam (FIB) image, copper diffusion does not occur. As illustrated in example FIG. 14(c), however, as a result of the annealing process at 450° C., it can be appreciated from the FIB that the pad is considerably dirty and the entire aluminum pad is changed into copper. Therefore, it can be appreciated that the copper diffusion to the aluminum pad is caused due to a heat treatment being a subsequent process.

Example FIGS. 15(a) and 15(b) illustrate cross-sectional images of the obtained pad (left image) and third metal line 28 when TiSiN (2×100) and TiSiN (4×50) each is used as third diffusion barrier layer 36. The images illustrated in example FIGS. 15(a) and 15(b) are obtained when performing the annealing for 30 minutes at 450° C. using TiSiN(2×100) and TiSiN(4×50) as third diffusion barrier layer 36 and then confirming it with the optical device and the FIB. When using TiSiN (2×100) as third diffusion barrier layer 36, it can be appreciated from example FIG. 15(a) that there is locally the portion of copper diffusion. However, when using TiSiN (4×50) as third diffusion barrier layer 36, it can be appreciated from example FIG. 15(b) that copper is not diffused.

Example FIGS. 16(a) and 16(b) illustrate the FIB images of a center and an edge when TiSiN (4×50) as third diffusion barrier layer 36 is actually applied to the 90 nm NOR flash device. As can be appreciated from example FIGS. 16(a) and 16(b), copper diffusion generated when TiSiN (2×50) as third diffusion barrier layer 36 is applied is not shown at any portions when TiSiN (4×50) as third diffusion barrier layer 36 is applied.

Example FIGS. 17(a) and 17(b) are results of electrically measuring data in a target size of sheet resistance R_{C} and contact resistance R_{C} of a full point at a unit wafer when TiSiN (2×50) and TiSiN (4×50) as third barrier layer 36 are applied. Example FIG. 17(a) is a view showing the resistance characteristic per a kind of each diffusion barrier layer when the line width of second contact 26 is 0.210 μm. Example FIG. 17(b) is a view showing the resistance characteristic per a kind of each diffusion barrier layer when the line width of third metal line 28 is 0.44 μm. As illustrated in example FIG. 17(a), although the contact resistance is increased due to the thickness of TiSiN in a viewpoint of R_{C}, it can be appreciated that there are few problems. As illustrated in example FIG. 17(b), even in a viewpoint of the sheet resistance, it can be appreciated that there are few differences in TiSiN (2×50) and TiSiN (4×50).

It can be appreciated that the use of Cu/low-k as illustrated in example FIG. 2 is better about 40% or more in R_{C} delay than in the use of Al/USG as illustrated in example FIG. 5. Also, it can be appreciated that the contact resistance from conductive region 12 to second contact 26 and the sheet resistance from first metal line 16 to third metal line 28 are excellent. It can be appreciated that there is few problem of the open and the short in first metal line 16 being the most vulnerable portion in the 90 nm process. It can be appreciated from the images obtained by the SEM and the TEM that the oxygen plasma damage on the trench due to the use of low-k or the shrinkage and bowing phenomenons of low-k due to the wet strip do not occur. However, it can be appreciated that the copper diffusion to the pad, which is not generated through the use of Al and USG in the Cu/low-k BELO process, may occur by the heat treatment being the subsequent process. However, it can be appreciated through SEM image that the diffusion of copper to third metal line 28 may be prevented since TiSiN (4×50) is used as third diffusion barrier layer 36.

As described above, the NOR flash device and the method for fabricating the device uses copper lines 16, 20, 22, and 26 and low-k (k=3.0) for the BEOL, making it possible to improve 40% or more in the time constant delay than the use of USG and aluminum, prevent the oxygen plasma damage of the trench due to use of low-k or the shrinkage or bowing phenonmenons of low-k due to the wet strip from being generated, and previously remove the copper diffusion phenonmenon to the aluminum pad by the application of TiSiN (4×50) as third diffusion barrier layer 36 at the lowermost surface of aluminum being third metal line 28.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a substrate having a conductive region;
a first intermetal dielectric layer formed on the substrate;
a first metal line formed on the conductive region;
a second intermetal dielectric layer formed on the first metal line and the first inter metal dielectric;
a first contact extending through the second intermetal dielectric layer; and
a second metal line connected to the first metal line through the first contact,
wherein at least one of the first contact and the first and second metal lines is composed of copper and at least one of the first and second inter metal dielectric layers is composed of a low diectrice material.

2. The apparatus of claim 1, further comprising:
a third intermetal dielectric layer formed on the second metal line and the second intermetal dielectric layer;
a second contact extending through the third intermetal dielectric layer; and
a third metal line connected to the second metal line through the second contact,
wherein the second contact is composed of copper and the third intermetal dielectric layer comprises a low-k dielectric material.

3. The apparatus of claim 2, wherein the third metal line is composed of at least one of copper and aluminum.

4. The apparatus of claim 2, further comprising:
a first diffusion barrier layer formed between the first metal line and the second intermetal dielectric layer; and
a second diffusion barrier layer formed between the second metal line and the third intermetal dielectric layer.

5. The apparatus of claim 4, wherein the third diffusion barrier layer is composed of a multi-layer structure.

6. The apparatus of claim 5, wherein the third diffusion barrier layer is composed of TiSiN.

7. The apparatus of claim 6, wherein the multi-layer structure comprises between 2-4 layers.

8. The apparatus of claim 7, wherein the thickness of each layer is between 15 Å to 100 Å.

9. The apparatus of claim 1, wherein at least one of the first and second intermetal dielectric layers comprises a multi-layer structure.

10. The apparatus of claim 1, wherein the multi-layer structure comprises:
a low-k dielectric material layer; and
a TEOS oxide layer formed on the low-k dielectric material layer.

11. The apparatus of claim 2, wherein the third intermetal dielectric layer comprises:
a low-k dielectric material layer; and
a TEOS oxide layer formed on the low-k dielectric material layer.

12. A method comprising:
forming a conductive region in a substrate; and then
forming a first intermetal dielectric layer on the substrate, the first intermetal dielectric layer having a trench exposing the conductive region; and then
forming a first metal line in the trench; and then
forming a second intermetal dielectric layer on the first metal line and the first intermetal dielectric, the second intermetal dielectric layer having a hole exposing the first metal line; and then
forming a first contact and a second metal line in the hole,
wherein at least one of the first contact and the first and second metal lines is composed of copper and at least one of the first and second intermetal dielectric layers is composed of a low-k dielectric material.

13. The method of claim 12, wherein the first contact and the second metal line is formed by a damascene process.

14. The method according to claim 12, further comprising, after forming the first contact and the second metal line:
forming a third intermetal dielectric layer on the second metal line and the second intermetal dielectric layer, the third intermetal dielectric layer having a via exposing the second metal line; and then
forming a second contact in the via; and then
forming a third metal line connected to the second contact,
wherein the second contact is composed of copper and the third intermetal dielectric layer is composed of a low-k dielectric material.

15. The method of claim 14, further comprising the steps of:
forming a first diffusion barrier layer on the first metal line and the first intermetal dielectric layer, after forming the first metal line and before forming the second intermetal dielectric layer; and then
forming a second diffusion barrier layer on the second metal line and the second intermetal dielectric layer, after forming the first contact and the second metal line and before forming the third intermetal dielectric layer; and then
forming a third diffusion barrier layer on the second contact, after forming the second contact and before forming the third metal line,
wherein the second intermetal dielectric layer is formed on the first diffusion barrier layer, the third intermetal dielectric layer is formed on the second diffusion barrier layer and the third metal line is formed on the third diffusion barrier layer.

16. The method of claim 15, wherein the third diffusion barrier layer is composed of TiSiN.

17. The method of claim 16, wherein the third diffusion barrier layer is composed of a multi-layer structure having between 2-4 layers.

18. The method of claim 17, wherein the thickness of each layer in the multi-layer structure is between 15 Å to 100 Å.

19. The method of claim 15, wherein forming the first intermetal dielectric layer comprises:
forming a first low-k dielectric material layer on the substrate; and then
forming a first TEOS oxide layer on the low-k dielectric material layer.

20. The method of claim 19, wherein forming the second intermetal dielectric layer comprises:
forming a second low-k dielectric material layer on the first metal line and the first TEOS oxide layer; and
forming a second TEOS oxide layer on the second low-k dielectric material layer.
